(19) United States
(12) Patent Application Publication
(10) Pub. No.: US 2007/0248798 A1
(43) Pub. Date: Oct. 25, 2007

(54) CIRCUIT BOARD MANUFACTURING PROCESS, CIRCUIT BOARD MANUFACTURED BY THE PROCESS, AND CIRCUIT BOARD MANUFACTURING APPARATUS

(75) Inventors: Yuji Tsuruoka, Kawasaki-shi (JP); Takashi Mori, Tokyo (JP); Nobuhito Yamaguchi, Tokyo (JP); Masao Furukawa, Yokohama-shi (JP); Seiichi Kamiya, Yokohama-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/737,265

(22) Filed: Apr. 19, 2007

(30) Foreign Application Priority Data
Apr. 19, 2006 (JP) 2006-116094

(51) Int. Cl. H05K 3/00; B32B 15/04

(52) U.S. Cl. 428/195.1; 427/98.4; 428/457

(57) ABSTRACT

When forming circuit patterns by ejecting a minute amount of a conductive pattern solution and insulating pattern solution from a liquid ejection head in the form of an ink-jet head, a break or short circuit in a circuit caused by an ejection malfunction is prevented. During the forming process of the circuit patterns, preliminary ejection of the liquid ejection head for forming the circuit patterns is carried out toward an area without the circuit patterns. In addition, the preliminary ejection is carried out at intervals less than an ejection interruption time that might cause the ejection malfunction.

### BACKGROUND OF THE INVENTION

1. Field of the Invention

The present invention relates to a circuit board, and a manufacturing apparatus and manufacturing process for fabricating the circuit board, which are widely utilized for electronic devices.

2. Description of Related Art

Circuit boards, on which semiconductors such as LSIs and various electronic components are mounted, are widely applicable as central components of a variety of electronic devices, communications equipment, computers and the like. The main stream circuit boards applied to these devices are those that employ as a base material a composite material of a reinforcing material such as ceramics or glass fiber and a synthetic resin such as epoxy resin. As for circuit boards incorporated into small-scale devices such as mobile phones, cameras and the like, however, some of them employ polyester resin or aramid resin as the base material to obtain flexibility in order to improve the mounting capacity of a limited space.

As for circuit patterns formed on the circuit boards, most of them were formed in a single layer on one side or both sides of the boards at one time. At present, however, the mainstream is multilayer structures such as 8-layer and 16-layer arrangements in accordance with the requirements for miniaturization of the equipment to which the boards are applied and the high-density placement of the components. In addition, the circuit patterns themselves make rapid progress toward finer and higher-density design with a speedup and miniaturization of electronic circuits.

As a circuit pattern forming process on a circuit board, although a variety of processes have been put to practical use, the mainstream up to now is a subtractive process. The subtractive process is a process for obtaining circuit patterns by employing a copper-clad laminate as a base material and by removing unwanted portions of conductors by etching. The subtractive process, however, includes many processes such as a drilling process of a base material, electroless plating process, patterning process with a dry film, electroplating process, etching process and solder peeling process. This increases the ratio of the processing costs to the manufacturing costs of the circuit boards. Thus, reduction of the processing costs has been a great problem in manufacturing the circuit boards. In addition, since in the plating process and etching process waste fluid flows out, the waste fluid processing also offers an environmental impact reduction problem.

To solve the problems, Japanese Patent Laid-Open Nos. 2003-309369 and 11-163499/1999 disclose a circuit board forming process without using the subtractive process. These documents disclose a process of forming circuit boards by ejecting a solution (conductive pattern solution) that dissolves a component that will exhibit conductivity and a solution (insulating pattern solution) that dissolves a component that will exhibit insulation onto a surface of a base material through liquid ejection heads employing an ink-jet system. Here, Japanese Patent Laid-Open No. 2003-309369 describes a process of forming a circuit board by alternately stacking conductive patterns and insulating patterns. On the other hand, Japanese Patent Laid-Open No. 11-163499/1999 describes a process of forming a circuit board by ejecting both the conductive pattern solution and insulating pattern solution for a single layer to form a circuit pattern layer consisting of a conductive pattern and insulating pattern, and by forming (stacking) circuit pattern layers on that layer in the same manner.

When ejecting the solutions such as a conductive pattern solution and an insulating pattern solution through these liquid ejection heads (also shortly called “heads” from now on), the ejection can be performed without any problem as long as the solutions are ejected continuously from the nozzles of the heads. However, when resuming the ejection after interrupting the ejection of the solutions, ejection malfunctions may take place such as reductions in the speed and amounts of solutions ejected from the nozzles and variations in the ejecting directions. In extreme cases, an ejection failure may occur. The ejection malfunction and ejection failure result from an increase of the viscosity of the solutions which makes the ejection difficult. This is because the solutions remaining within the nozzles during the ejection interruption are exposed to outside air, and the volatile compounds (solvent and the like) in the solutions vaporize. In particular, as for the circuit board manufacturing apparatus employing an on-demand ink-jet system, the ejection malfunction is highly likely to take place because the interruption of the solution ejected from the nozzles can occur frequently in accordance with the patterns to be formed. When the ejection malfunction or the like occurs, forming of the circuit patterns is hampered, resulting in breaks or short circuits in the circuit patterns.

Thus, to remove the thickened solutions remaining in the nozzles and to refill (refresh) the nozzles with the solutions within a desired viscosity range, a method is generally known which carries out, in addition to the essential ejection operation (primary ejection operation) for forming the conductive patterns and insulating patterns, an ejection operation (secondary ejection operation) having nothing to do with the pattern forming. It corresponds to the operation referred to as “preliminary ejection” in the ink-jet printing technology, and hence the secondary ejection operation is called preliminary ejection from now on for convenience sake. The preliminary ejection is carried out conventionally to remove thickened solutions accumulated up to the time of starting the forming (drawing) of the circuit patterns by actually ejecting the solution. As for the process, a variety of proposals has been made.

For example, Japanese Patent Laid-Open No. 2003-282245 discloses a technique that provides a preliminary ejection area outside a pattern forming region; and circumvents the ejection malfunction by carrying out the preliminary ejection to that area before the pattern drawing to eject thickened solutions and to refill the solution with a desired viscosity. In addition, Japanese Patent Laid-Open No. 2004-81988 tries to prevent the ejection malfunction effectively, in a configuration that carries out the preliminary ejection during the relative movement of the heads and a work on which the patterns are formed, by integrating the preliminary ejection area into the work to place the preliminary ejection area as close to the pattern forming area as possible.

Recently, electronic circuits have been extremely tightly integrated, and the circuit boards become ever denser rapidly. Thus, it is essential to make the circuit patterns still finer. To achieve this, it is necessary to reduce the ejection amount per dot of the conductive pattern solution and insulating pattern solution ejected from the heads. To reduce the ejection amount, it is effective to reduce the nozzle tip diameter. However, reducing the nozzle diameter will cause the ejection malfunction resulting from the thickened solutions in the nozzles to take place more easily for that. In particular, as for the heads for ejecting droplets of a few picoliters to a few tens of picoliters, which are likely to be used for forming circuit boards with high-density patterns, it is confirmed that the ejection interruption of only about 50-100 msec can bring about the ejection malfunction.

FIG. 20 is a schematic diagram of a circuit board formed by ejecting a conductive pattern solution through a head. The head 1 having a plurality of nozzles 2 disposed forms conductive patterns by ejecting the conductive pattern solution onto the base material 3 while moving from the position in FIG. 20 in the direction indicated by the arrow M, which differs from the nozzle array direction. In the configuration shown in FIG. 20, the dimension of the base material 3 in the vertical direction is greater than the width of the nozzle array. Thus, the head 1 is returned to its original predetermined position, and the base material 3 is shifted in the direction of the arrow S orthogonal to the head moving direction (M direction) by an amount of the nozzle array width. After that, the conductive patterns are formed with moving the head 1 in the M direction. In this way, the conductive patterns are formed on the entire surface of the base material 3.

Among the forming regions of the conductive patterns, there are a region A without any conductive patterns and a region B for mounting an electrical component such as an IC. During the time the head passes by the region A, that is, for tens of milliseconds to several hundred milliseconds, the ejection of the conductive pattern solution may interrupt. Thus, when the head ejecting minute droplets is used in particular, the ejection malfunction can take place because of the thickened solution remaining in the nozzles when forming the next conductive pattern C.

As described above, in the circuit board forming, the ejection malfunction can occur even during the forming operation of the circuit patterns. Therefore, by carrying out only the preliminary ejection before the pattern forming as described in Japanese Patent Laid-Open Nos. 2003-282245 and 2004-81988, the ejection malfunction cannot be prevented effectively, and hence highly reliable circuit boards cannot be formed.

### SUMMARY OF THE INVENTION

The present invention is implemented to solve the foregoing problems. It is therefore an object of the present invention to contribute to providing a highly reliable, high density circuit board by preventing a break or short circuit resulting from an ejection malfunction during forming the circuit pattern by ejecting a minute amount of solution from a liquid ejection head.

In the first aspect of the present invention, there is provided a manufacturing process of a circuit board, which employs a head movable with reference to a base material, and forms a pattern for configuring a circuit in a region on the base material by ejecting a solution to the region, the manufacturing process of the circuit board comprising the steps of: carrying out a primary ejection operation of the head for forming the pattern on the base material; and carrying out a secondary ejection operation of the head for maintaining ejection performance of the head in a good condition, the secondary ejection operation being independent of the pattern formation, wherein when an ejection interruption time occurs that can cause an ejection malfunction during the primary ejection operation, the secondary ejection operation is carried out toward an area without the pattern formed by the primary ejection operation in the region.

In the second aspect of the present invention, there is provided a circuit board on which a pattern for configuring a circuit is formed by employing a head movable with reference to a base material, and by ejecting a solution to a region on the base material to form the circuit, the circuit board comprising: the pattern formed by carrying out a primary ejection operation of the head on the base material; and a pattern that does not configure the circuit, formed by carrying out a secondary ejection operation of the head for maintaining ejection performance of the head in a good condition, the secondary ejection operation being independent of the pattern formation for the circuit, wherein the pattern that does not configure the circuit is formed on an area without the pattern formed by the primary ejection operation to configure the circuit, when an ejection interruption time occurs that can cause an ejection malfunction during the primary ejection operation.

In the third aspect of the present invention, there is provided an apparatus for manufacturing a circuit board, which employs a head movable with reference to a base material, and forms a pattern for configuring a circuit in a region on the base material by ejecting a solution to the region, the apparatus comprising: means for making the head carry out a primary ejection operation for forming the pattern on the base material and a secondary ejection operation for maintaining ejection performance of the head in a good condition, the secondary ejection operation being independent of the pattern formation; and means for making the head carry out the secondary ejection toward an area without the pattern formed by the primary ejection operation in the region, when an ejection interruption time occurs that can cause an ejection malfunction during the primary ejection operation.

According to the present invention, during the forming process of the circuit pattern by the primary ejection operation of the head, the secondary ejection operation (preliminary ejection) having nothing to do with the circuit pattern is carried out on a region without the circuit pattern. In addition, the preliminary ejection is carried out at intervals less than an ejection interruption time that might cause the ejection malfunction. This makes it possible to effectively prevent a break or short circuit in a circuit caused by the ejection malfunction. In addition, since the preliminary ejection can be performed simultaneously during the circuit pattern forming process, the throughput is increased.

Further features of the present invention will become apparent from the following description of exemplary embodiments (with reference to the attached drawings).

### BRIEF DESCRIPTION OF THE DRAWINGS

FIG. 1 is a schematic perspective view showing a mechanical structure of a circuit board manufacturing apparatus to which the present invention is applicable; FIG. 1 is a schematic perspective view showing a mechanical structure of a circuit board manufacturing apparatus to which the present invention is applicable;

FIG. 2 is a block diagram showing a configuration of a control system of the circuit board manufacturing apparatus of FIG. 1;

FIG. 3A-FIG. 3C are schematic diagrams according to a first embodiment of the present invention, which show consecutive 3-layers when insulating pattern layers and a conductive pattern layer are stacked alternately on a base material;

FIG. 4 is a schematic diagram showing a preliminary ejection allowing area of the conductive pattern solution on a layer of interest according to the first embodiment of the present invention;

FIG. 5 is a schematic diagram showing a pattern finally obtained through the forming of an essential conductive pattern and the preliminary ejection within the area as shown in FIG. 4, which corresponds to a partially expanded view of FIG. 3B;

FIG. 6 is a flowchart illustrating a control procedure for implementing the operation of the first embodiment;

FIG. 7 is a schematic diagram showing a pattern finally obtained through the forming of an essential conductive pattern and the preliminary ejection different from that of FIG. 4 within the area as shown in FIG. 4, which corresponds to a partially expanded view of FIG. 3B;

FIG. 8A-FIG. 8C are schematic diagrams according to a second embodiment of the present invention, which show consecutive 3-layers when a plurality of circuit pattern layers, each including both a conductive pattern and an insulating pattern, are stacked on a base material;

FIG. 9 is an enlarged view showing the region A2 and its neighborhood of FIG. 8B when the preliminary ejection of the second embodiment is carried out;

FIG. 10 is a flowchart illustrating a control procedure for implementing the operation of the second embodiment;

FIG. 11A and FIG. 11B are schematic diagrams illustrating the operation during the procedure of FIG. 10;

FIG. 12 is an enlarged view showing the region A2 and its neighborhood of FIG. 8B when the preliminary ejection of a variation of the second embodiment is carried out;

FIG. 13A-FIG. 13C are schematic diagrams according to a third embodiment of the present invention, which show consecutive 3-layers when a plurality of circuit pattern layers, each including both a conductive pattern and an insulating pattern, are stacked on a base material;

FIG. 14A and FIG. 14B are schematic diagrams illustrating a decision mode of the preliminary ejection allowing area in the third embodiment;

FIG. 15 is a flowchart illustrating a control procedure for implementing the operation of the third embodiment;

FIG. 16A-FIG. 16C are schematic diagrams according to a fourth embodiment of the present invention, which show consecutive 3-layers when a plurality of circuit pattern layers are stacked;

FIG. 17 is a schematic diagram illustrating a decision mode of the preliminary ejection allowing area in the fourth embodiment;

FIG. 18A-FIG. 18C are schematic diagrams illustrating the operation during the procedure of FIG. 10;

FIG. 19 is a flowchart illustrating a control procedure for implementing the operation of the fourth embodiment; and

FIG. 20 is a schematic diagram of a circuit board formed by ejecting a conductive pattern solution through a head, which illustrates problems to be solved by the present invention.

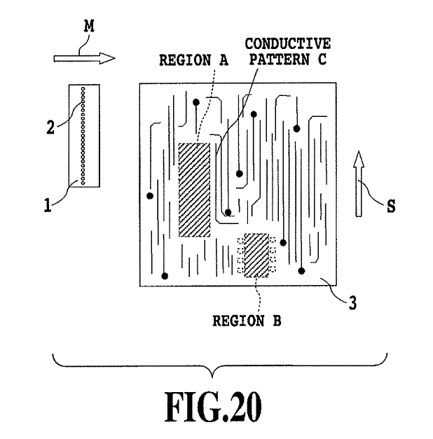

### DESCRIPTION OF THE EMBODIMENTS

The invention will now be described with reference to the accompanying drawings.

### Configuration of Circuit Board Manufacturing Apparatus

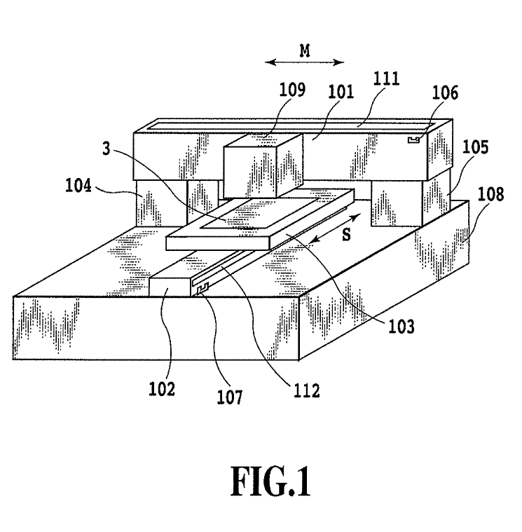

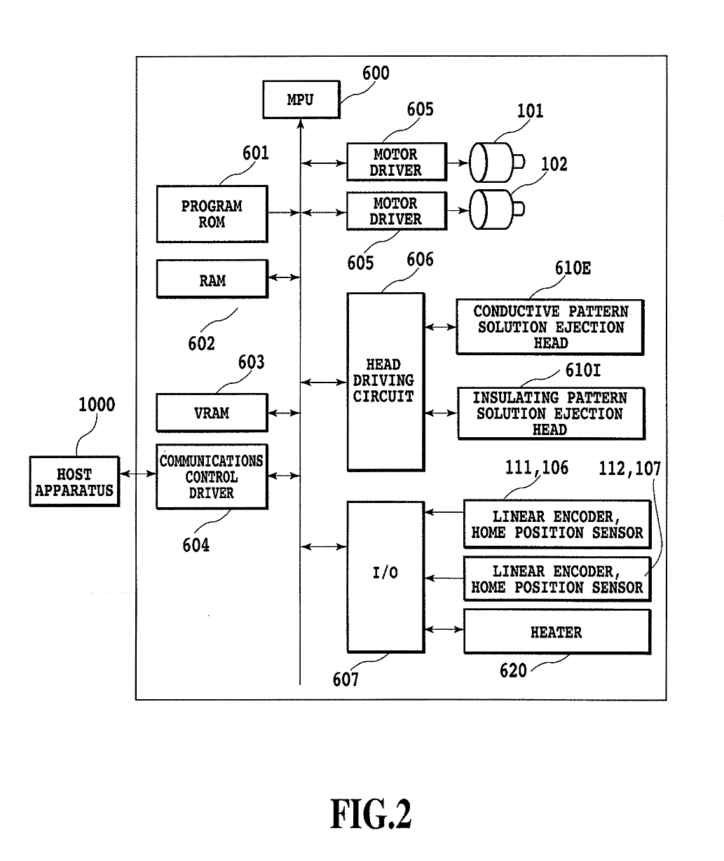

FIG. 1 is a schematic perspective view showing a mechanical structure of a circuit board manufacturing apparatus to which the present invention is applicable; and FIG. 2 is a block diagram showing a configuration of a control system thereof.

On a carriage 109, two heads 610E and 610I (not shown in FIG. 1) are mounted for ejecting a conductive pattern solution and an insulating pattern solution onto a base material 3, respectively. As the heads 610E and 610I, it is possible to employ a head that has, on its surface facing the base material 3, nozzles arranged in a direction different from a moving direction (M direction) of the carriage 109. In the following description, the two heads 610E and 610I are referred to as a conductive pattern solution ejection head (corresponding to a first head) and an insulating pattern solution ejection head (corresponding to a second head), respectively, or simply as heads.

Furthermore, on the carriage 109, two tanks can be mounted which supply the heads 610E and 610I with the conductive pattern solution and the insulating pattern solution, respectively. The tanks can be mounted on the carriage 109 to be integrated with the heads. Alternatively, the tanks can be mounted on a fixed portion of the apparatus to supply these heads with the solutions via tubes or the like.

As the conductive pattern solution, a solution is generally employed which includes a metal colloid of a material such as Al, Ag, SnO₂ and the like from a point of view of the conductivity. As for the particle diameters of the metal colloid, a few tens to a few hundreds of nanometers are preferable from a point of view of the uniformity and stability of the circuit patterns. As the insulating pattern solution, a solution is preferably employed which includes insulating minute particles such as those of silica, alumina, calcium carbonate, magnesium carbonate and the like. The insulating pattern solution, however, is not limited to them as long as exhibiting insulation ultimately. As the base material 3, materials are generally enumerated such as porous ceramics obtained by sintering alumina, silica, aluminum nitride, barium titanate, zirconia and the like; porous resin film using polyolefin or inorganic filler as a chief material; and glass fiber. It is preferable in the present embodiment, which includes a heating fixation process and sintering process, to employ high-temperature porous ceramics.

The carriage 109 is mounted movably in the M direction of FIG. 1 over a stage 103 carrying the base material 3, by driving means (called “CR linear motor” from now) 101 in the form of a linear motor. On the other hand, the stage 103 is movable in the S direction of FIG. 1 orthogonal to the traveling direction of the carriage 109, by driving means (called “LF linear motor” from now on) 102 in the form of a linear motor.

The LF linear motor 102 is fixed to a surface plate 108 at high rigidity, and the surface of the stage 103, on which the base material 3 is mounted, is always maintained in parallel with the surface plate in spite of the movement of the stage. In addition, the CR linear motor 101 is fixed over the surface plate 108 via bases 104 and 105 at high rigidity, and the carriage 109 is adjusted in such a manner as to move in parallel with the surface plate, that is, with the surface of the stage 103.

The CR linear motor 101 and LF linear motor 102 are provided with linear encoders 111 and 112 and home position sensors 106 and 107, respectively, which are utilized for servocontrol input at a time of the linear motor driving. The output of the linear encoder 111 is also used for controlling the ejection timing of the conductive pattern solution ejection head 610E and insulating pattern solution ejection head 610I. To form circuit patterns with a width of a few tens of micrometers, it is enough to employ the linear encoders with a high resolution of about 0.5 μm.

The stage 103 supporting the base material 3 can have a built-in heater 620. Heating the formed circuit patterns with the heater can expedite the vaporization of the solvent, that is, the fixation of the circuit patterns. In connection with the heater 620, a temperature sensor for regulating the temperature may be provided.

In FIG. 2, reference numerals 605 designate motor drivers for driving the CR linear motor 101 and LF linear motor 102, and the reference numeral 606 designates a head driving circuit for driving the heads 610E and 610I. The reference numeral 607 designates an input/output (I/O) port for receiving signals from the encoders 111 and 112 and the home position sensors 106 and 107, and for supplying a driving signal to the heater 620.

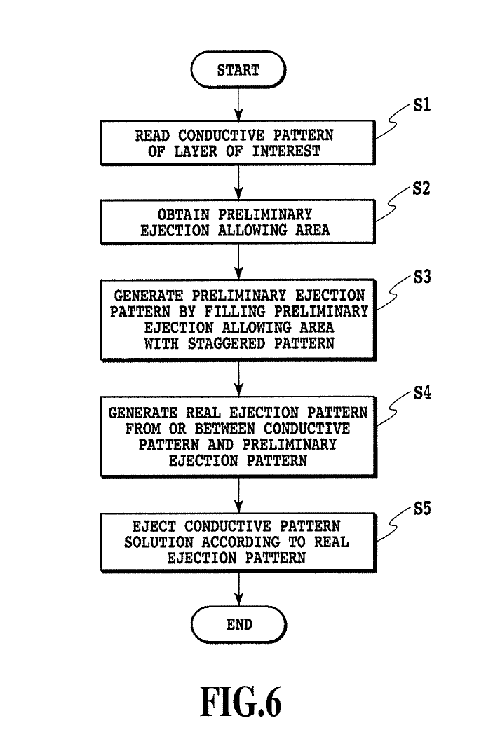

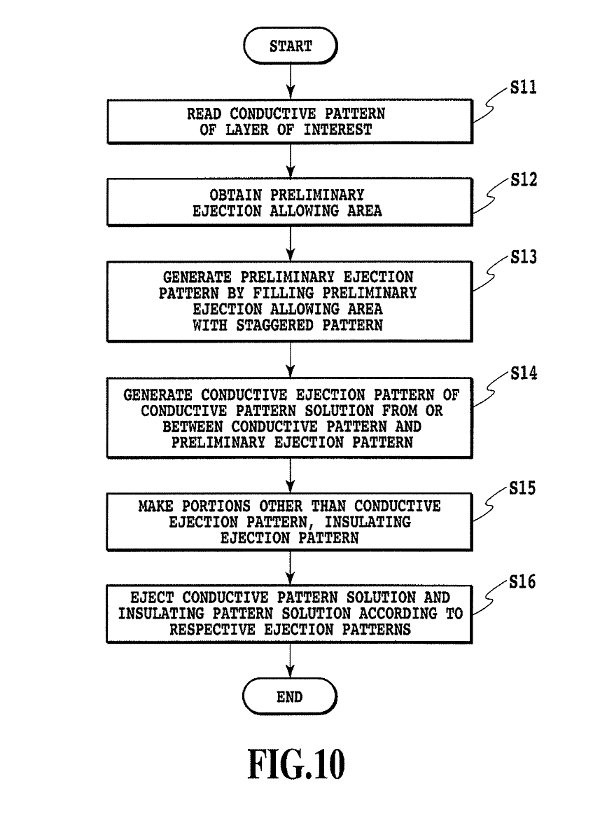

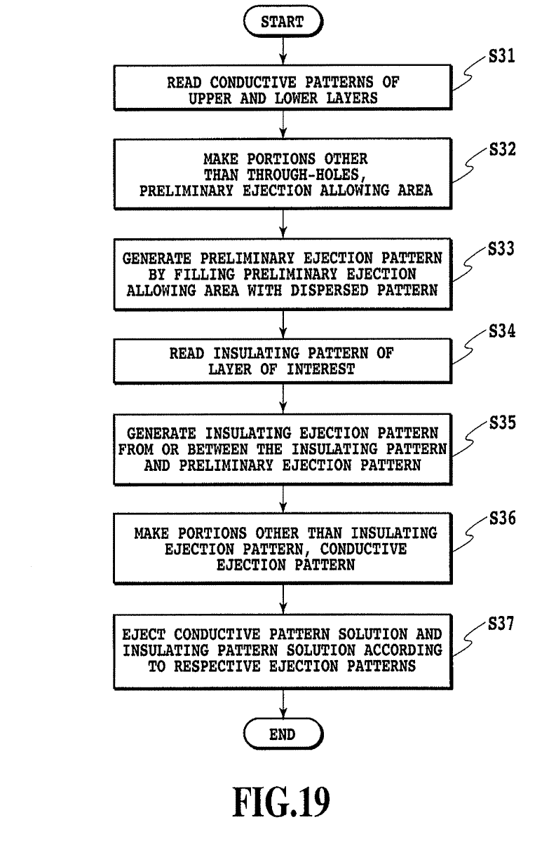

The reference numeral 600 designates an MPU for controlling various portions of the apparatus. The MPU 600 executes control programs corresponding to control procedures stored in a program ROM 601 using a working RAM 602 as needed, which will be described later with reference to FIG. 6, FIG. 10 and FIG. 19. The reference numeral 604 designates a communications control driver connected to a host apparatus 1000 in the form of a computer. The communications control driver 604 receives drawing data for forming the circuit patterns from the host apparatus 1000, and transmits the status and the like of the circuit board manufacturing apparatus to the host apparatus 1000. The drawing data is arranged in a VRAM 603 in correspondence with the position of the base material 3. Then, according to the drawing data are controlled the ejection operation of the heads 610E and 610I and the moving operation of the carriage 109 and stage 103.

More specifically, according to the drawing data of the circuit patterns, the following operations are carried out.

Move the stage 103 to a predetermined position by the LF linear motor 102; and

Eject the conductive pattern solution and insulating pattern solution to predetermined locations on the base material 3 by driving the heads 610E and 610I with scanning the carriage 109 by the CR linear motor 101.

Repeating these operations by the number of times necessary makes it possible to form the circuit patterns consisting of the conductive patterns and insulating patterns on the base material 3.

The circuit board manufacturing apparatus of the present embodiment can fix the formed circuit patterns quickly with the heater 620. Accordingly, stacking the circuit patterns successively on the fixed circuit patterns enables forming a multilayer circuit board. In the formed circuit patterns, however, the solvents in the solution are left, and the metal colloid for implementing the conductivity continues to exist without change. Therefore to further improve the performance of the circuit board in terms of the electrical insulation and conductivity, it is desirable to eliminate the solvents completely from the formed circuit board, and to carry out baking processing to sinter the metal colloid and to implement the conductivity with a baking apparatus installed separately.

As for the circuit board manufacturing apparatus with the foregoing configuration, several preferred embodiments will be described below which are suitable for accomplishing the object of the present invention to prevent the ejection malfunction during the operation of forming the circuit patterns. These embodiments are characterized by that the preliminary ejection is conducted during the forming process of the circuit patterns. To perform the preliminary ejection before the circuit pattern forming, however, the techniques described in Japanese Patent Laid-Open Nos. 11-163499/1999 and 2004-81988 are applicable.

### Embodiment 1

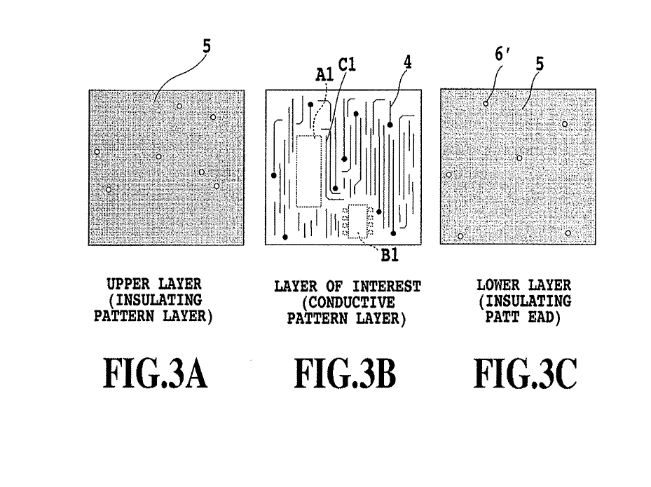

FIG. 3A-FIG. 3C are schematic diagrams illustrating consecutive 3-layers when insulating pattern layers and a conductive pattern layer are alternately stacked on a base material. FIGS. 3A and 3C illustrate upper and lower insulating pattern layers, respectively, between which the conductive pattern layer of interest (FIG. 3B) is sandwiched. To obtain such a multilayer circuit board, it is enough to apply the forming data of the insulating pattern solution and the forming data of the conductive pattern solution sequentially in the foregoing apparatus configuration.

In FIGS. 3A and 3C illustrating the insulating pattern layers, shaded portions 5 each designate an insulating pattern, and each portion 6′ designated by a white circle represents a via hole. In FIG. 3B illustrating the conductive pattern layer, each portion 4 designated by a solid line and a black circle represents a conductive pattern, and each portion designated by broken lines indicates a section for mounting an IC or the like, to which no conductive pattern solution is applied.

The insulating pattern layers on the top and bottom of the conductive pattern layer must be insulated from the conductive patterns 4 except for the via holes 6′ serving as through connections between the conductive patterns 4 and conductive pattern layers to be disposed on the top and bottom. To achieve this, as illustrated in FIGS. 3A and 3C, the insulating pattern solution is applied in a solid filled pattern except for the via holes 6′. In other words, since the insulating pattern solution is almost continuously ejected during the formation of the insulating pattern layers, no ejection malfunction of the insulating pattern solution ejection head 610I will occur during the circuit pattern forming operation.

In contrast with this, as for the conductive pattern layer (FIG. 3B), there are regions A1 and B1 in which the conductive pattern 4 is absent or sparse. As for these regions, since the conductive pattern solution ejection head 610E interrupts its ejection, the ejection malfunction might occur in a conductive pattern C1 at which the next ejection is resumed.

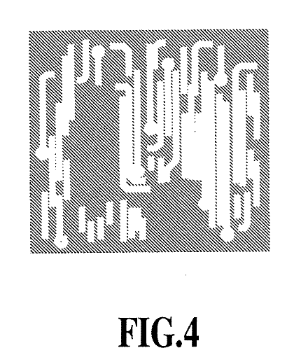

In view of this, paying attention to the insulating pattern layers on the top and bottom of the conductive pattern layer, the inventors of the present invention employs a new preliminary ejection process. As described above, since the insulating patterns 5 have a solid filled insulation pattern except for the via holes 6′, the conductive patterns 4 are completely insulated except for the via holes 6′. Accordingly, the preliminary ejection of the conductive pattern solution can be carried out as long as the ejection is limited within the area (shaded portion in FIG. 4) separated from the conductive patterns 4 by a distance greater than or equals to an electrically isolable distance as illustrated in FIG. 4. In other words, no problem will occur because the conductive patterns formed by the preliminary ejection are electrically independent of the essential conductive patterns. Here, the term “electrically isolable distance” means a distance that satisfies the electrical characteristics of the circuit board, that is, the standard of the insulating resistance, withstand voltage and the like. As long as the distance between the essential conductive patterns and the conductive patterns formed by the preliminary ejection meet the standard, the performance of the circuit board does not bring about any problem. In addition, although the term “preliminary ejection allowing area” refers to an area surrounded by the patterns (conductive patterns such as C1 in the present embodiment) for configuring the circuit, the area must not be surrounded completely without allowing any gap.

As important electrical characteristics of the printed circuit board, there is insulation resistance between insulation resistance between conductors. The distance between two conductors required to meet the standard of the insulation resistance will be greatly changed due to conditions of the conductors, difference of potential between the conductors, or material properties of the insulating patterns such as the insulation resistance and surface resistance. For example, a suitable distance between the two conductors will be changed due to whether conductors are disposed such as a surface pattern layer or covered with the insulating patterns such as an underlying layer. In a commonly used circuit board, it is sufficient that the distance between the conductors is 100 micrometers(μm) or more. The distance the carriage 109 travels during an ejection interval (ejection interruption time) in which the ejection malfunction can occur is greater than the distance between the conductors. The head as used in the present embodiment that ejects ink of 1-10 pl has the ejection interruption time of about 10-300 microseconds. If the the carriage which mounts this head is scanned at 0.05-1 m/s, the distance the carriage 109 travels during the ejection interval is at least 500 μm. This is greater than 100 μm as the “electrically isolable distance”. Accordingly, the present embodiment determines the “electrically isolable distance” with reference to the distance over which the actually used head will not cause any ejection malfunction, and carries out the preliminary ejection. Although the present embodiment determines the distance at 200 μm by considering a margin of 100 μm, an optimum distance can be set considering the characteristics of the insulating patterns.

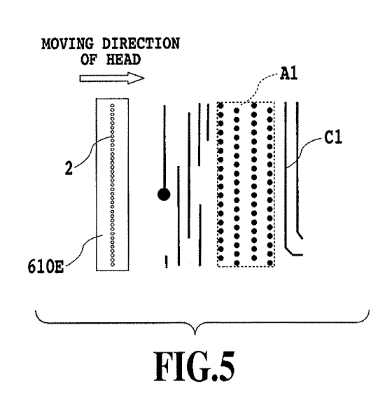

FIG. 5 shows a final pattern obtained by the formation of the essential conductive patterns and by the preliminary ejection carried out within the area as shown in FIG. 4, that is, the pattern formed by actually ejecting the conductive pattern solution. For clarification, FIG. 5 shows only an enlarged view of the region A1 and its neighborhood of FIG. 3B. In the example, the plurality of nozzles 2 arranged in the head 610E are divided into an odd-numbered nozzle group and an even-numbered nozzle group from an end of the nozzle arrangement. In the region A1, the nozzles in the two groups carry out alternate preliminary ejection, thereby forming the staggered pattern as shown in FIG. 5.

In this case, the reference is determined in such a manner that the preliminary ejection interval of the odd-numbered nozzle group and that of the even-numbered nozzle group are set shorter than the time during which the solutions within the nozzles are thickened and cause the ejection malfunction. Therefore, in the region A1, the conductive pattern solution in each nozzle is being refreshed successively to keep the reliable ejection performance without fail. In addition, the reference is determined in such a manner that the interval from the final preliminary ejection in the region A1 to the ejection of the next conductive pattern C1 is shorter than the time during which the ejection malfunction can occur. Thus, the ejection for the conductive pattern C1 is carried out normally, and hence no break or short circuit will occur in the conductive pattern C1.

Since the preliminary ejection is simultaneously carried out during the circuit pattern forming process, the throughput is increased. In addition, it becomes unnecessary to provide the base material or work with the preliminary ejection area adjacent to the pattern forming area. Alternatively even if the preliminary ejection area must be provided, it can be minimized. Thus, the present embodiment can flexibly cope with the changes in the size of the base material.

FIG. 6 is a flowchart illustrating the control procedure for implementing the foregoing operation.

First, the drawing data about the conductive patterns of the layer of interest is read (step S1). After that, according to the drawing data, an area separated from the conductive patterns by the electrically isolable distance is set as the preliminary ejection allowing area (step S2). Subsequently, the staggered preliminary ejection pattern data meeting the foregoing reference is generated within the preliminary ejection area (step S3). Then the OR operation is carried out between the conductive pattern data (essential conductive patterns) read at step S1 and the preliminary ejection pattern data generated at step S3 to obtain the real ejection pattern data for determining the actual ejection operation (step S4). As for these operations, the VRAM 603 area can be used as needed.

Then the head 610E is driven according to the real ejection pattern data to eject the conductive pattern solution (step S5). Thus, the conductive patterns as shown in FIG. 5 are obtained.

The preliminary ejection pattern (the pattern that does not configure the circuit) are not limited to those of FIG. 5. Any patterns can be employed as long as they can remove the thickened solutions remaining in the nozzles up to the time of the ejection for the conductive pattern C1 to be formed next.

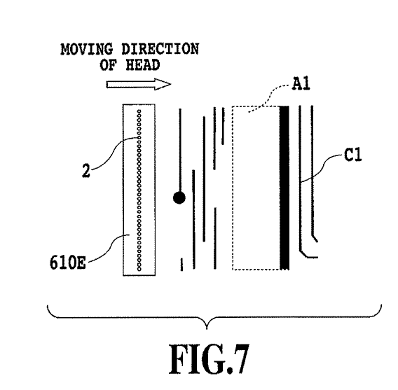

FIG. 7, which is an enlarged view showing the region A1 and its neighborhood in FIG. 3B as FIG. 5, illustrates one of the patterns. In the example, the preliminary ejection is carried out from all the nozzles just before the next conductive pattern C1 to form a solid filled pattern, thereby eliminating all the remaining thickened solutions. Immediately after that, the ejection for the conductive pattern C1 is performed. This also offers the same advantage as described above. In this case, the same procedure as that of FIG. 6 is applicable to the forming procedure of the preliminary ejection pattern. Specifically, instead of using the staggered pattern as the preliminary ejection pattern at step S3, the image, which consists of a solid filled pattern with a predetermined width at the edge of the preliminary ejection allowing area in the head scanning direction, can be employed as the preliminary ejection pattern. Thus, the pattern as shown in FIG. 7 is obtained.

The present embodiment is described by way of example that stacks the insulating pattern layers and the conductive pattern layer alternately to form the circuit board. The present invention, however, has the objective of preventing the ejection malfunction during the circuit pattern forming operation, and is primarily characterized by performing the preliminary ejection during the forming process of the circuit patterns. Thus, it does not matter whether the circuit board has a single-layer or multilayer structure. Accordingly, the present embodiment is effectively applicable to the circuit board as illustrated in FIG. 3B which has a single conductive pattern layer formed on the base material. The essential thing is that the conductive pattern layer has a portion without any conductive patterns, and the portion has a region separated from any of the conductive patterns by a distance greater than or equals to the electrically isolable distance; and that using that region as the preliminary ejection allowing area enables the preliminary ejection of the conductivity solution.

### Embodiment 2

Next, another embodiment will be described which forms the circuit board by stacking circuit pattern layers, each of which has its conductive patterns and insulating patterns formed by ejecting both the conductive pattern solution and insulating pattern solution.

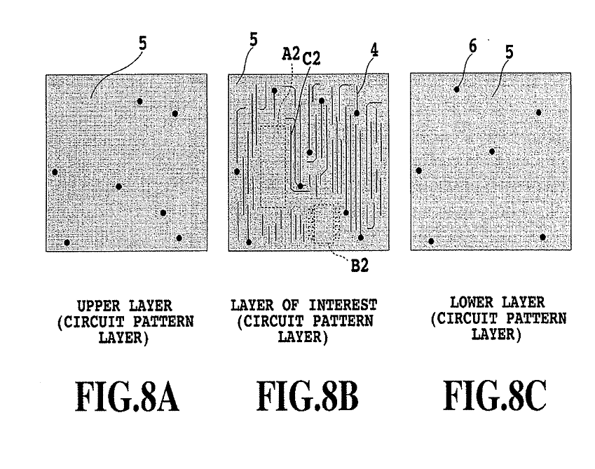

FIGS. 8A-8C are schematic diagrams showing consecutive three circuit pattern layers formed by stacking a plurality of circuit pattern layers, each of which has both the conductive patterns 4 and insulating patterns 5, on the base material 3. In the present embodiment, the entire region of each circuit pattern layer is filled with the conductive patterns 4 and insulating patterns 5. Both the layer of interest (FIG. 8B) and the upper and lower circuit pattern layers (FIGS. 8A and 8C) have its majority regions occupied by the insulating patterns. Thus, the ejection malfunction of the insulating pattern solution ejection head 610I does not occur during the formation of the insulating patterns.

In contrast with this, the conductive patterns of the layer of interest includes regions A2 and B2 in which the conductive patterns 4 are absent or sparse as in the first embodiment. In these regions, since the conductive pattern solution ejection head 610E interrupts its ejection, the ejection malfunction might occur in the conductive pattern C2 at which the next ejection is resumed.

On the other hand, the upper and lower two layers, between which the layer of interest is sandwiched, have solid filled insulation patterns except for connection portions 6, that is, conductor portions for connecting between the conductor patterns of the circuit pattern layers. Thus, the layer of interest is completely isolated except for the connection portions 6. For this reason, as in the embodiment 1, as for the regions separated from the conductive patterns by a distance greater than or equals to the electrically isolable distance as illustrated in FIG. 4, forming the conductive patterns with carrying out the preliminary ejection of the conductive pattern solution in these regions does not present any problem. In the present embodiment, the term “electrically isolable distance” has the same meaning as that of the embodiment 1.

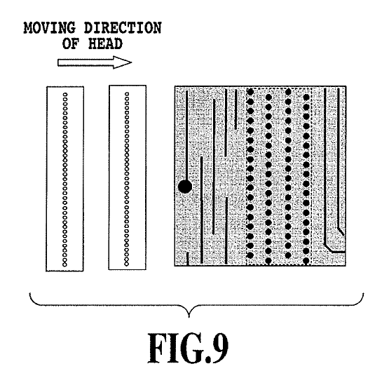

FIG. 9 is an enlarged view showing the region A2 and its neighborhood in FIG. 8B when carrying out the preliminary ejection of the present embodiment. In the present embodiment, the region A2, in which a solid filled insulating pattern is to be formed properly by ejecting the insulating pattern solution from the head 610I, includes a staggered pattern formed by partially carrying out the preliminary ejection of the conductive pattern solution from the head 610E.

In the present embodiment also, the reference is determined in such a manner that the preliminary ejection interval of the odd-numbered nozzle group and that of the even-numbered nozzle group are set shorter than the time during which the solutions within the nozzles are thickened and cause the ejection malfunction. Therefore, in the region A2, the conductive pattern solution in each nozzle is being refreshed successively to keep the reliable ejection performance without fail. In addition, the reference is determined in such a manner that the interval from the final preliminary ejection in the region A2 to the ejection of the next conductive pattern C2 is shorter than the time during which the ejection malfunction can occur. Thus, the ejection for the conductive pattern C2 is carried out normally, and hence no break or short circuit will occur in the conductive pattern C2.

FIG. 10 is a flowchart illustrating the control procedure for implementing the foregoing operation.

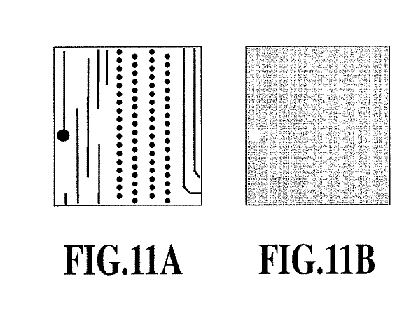

First, the conductive pattern data about the circuit patterns of the layer of interest and of the upper and lower layers stacked thereon are read (step S1). After that, according to the conductive patterns, each region in the layer of interest, which is separated from the conductive patterns by the electrically isolable distance, is set as the preliminary ejection allowing area (step S12). Subsequently, the staggered preliminary ejection pattern data meeting the foregoing reference is generated within the preliminary ejection allowing area (step S13). Then the OR operation is carried out between the conductive pattern data (essential conductive patterns) read at step S11 and the preliminary ejection pattern data generated at step S13. Thus, the real ejection pattern data (data for forming the patterns as shown in FIG. 11A) is obtained for determining the actual ejection operation of the conductive pattern solution for the layer of interest (step S14). In addition, the real ejection pattern data of the insulating pattern solution as shown in FIG. 11B are generated to fill the regions other than the conductive patterns with the insulating patterns (step S15). The real ejection pattern data of the insulating pattern solution are easily obtained by reversing the real ejection pattern data of the conductive pattern solution, for example. As for these operations, the VRAM 603 area can be used as needed, and the data arranged for each layer or for each conductive pattern or insulating pattern can be utilized.

Then the heads 610E and 610I are driven according to the real ejection pattern data to ejection the conductive pattern solution and insulating pattern solution (step S15) Thus, the conductive patterns as shown in FIG. 11A are obtained.

The preliminary ejection pattern is not limited to that of FIG. 9. Any patterns can be employed as long as they can remove the thickened solutions remaining in the nozzles by the time of ejection for the conductive pattern C2 to be formed next.

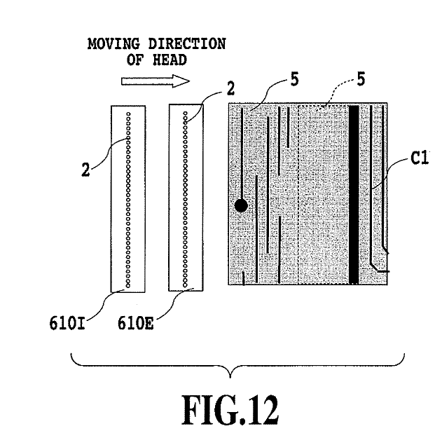

FIG. 12, which is an enlarged view showing the region A2 and its neighborhood in FIG. 8B as FIG. 9, illustrates one of the patterns. In the example, the preliminary ejection is carried out from all the nozzles of the head 610E just before the next conductive pattern C2 to form a solid filled pattern, thereby eliminating all the remaining thickened solutions. Immediately after that, the ejection for the conductive pattern C2 is performed. This also offers the same advantage as described above. In this case, the same procedure as that of FIG. 10 is also applicable to the forming procedure of the preliminary ejection pattern. Specifically, the pattern as shown in FIG. 12 can be obtained by generating the preliminary ejection pattern data representing a solid filled pattern with a predetermined width at the edge of the preliminary ejection allowing area in the head scanning direction at step S13.

### Embodiment 3

As the embodiment 2, the present embodiment is applicable to a case of forming the circuit board by stacking circuit pattern layers, each of which has the conductive patterns and insulating patterns formed by ejecting both the conductive pattern solution and insulating pattern solution. In the present embodiment, however, attention is paid to the circuit pattern layers forming the connection portions.

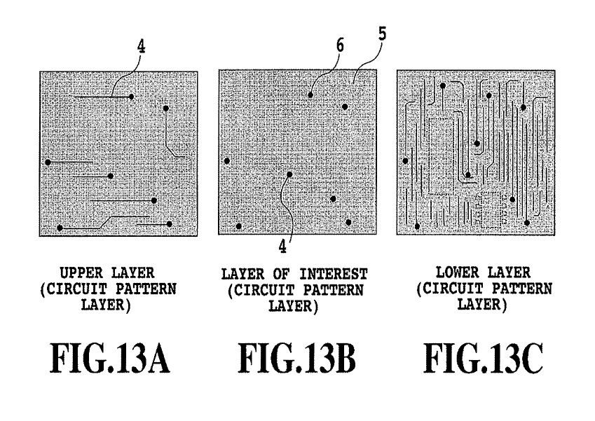

FIGS. 13A-13C are schematic diagrams showing consecutive three circuit pattern layers when stacking on a base material a plurality of circuit pattern layers, each including both conductive patterns 4 and insulating patterns 5. In the layer of interest as shown in FIG. 13B, the connection portions 6 are part of the conductive patterns 4, and the remaining portion is the insulating patterns 5. Accordingly, in trying to form the connection portions scattered as shown in the circuit patterns, the head 610E might cause the ejection malfunction, and can sometimes prevent the formation of the connection portions.

In view of this, paying attention to the relationships between the layer of interest and the upper and lower two layers between which it is sandwiched (FIGS. 13A and 13C), the inventors of the present invention employs a new preliminary ejection process of the conductive pattern solution. In the layer of interest, the regions other than the connection portions constitute the insulating layer for insulating from the upper and lower two layers. Thus, it is not necessary for the insulating patterns to cover the entire region actually. This is because even if the layer of interest were not present, a short circuit between the upper and lower two layers would take place only in the portions where the upper and lower conductive patterns overlap on each other.

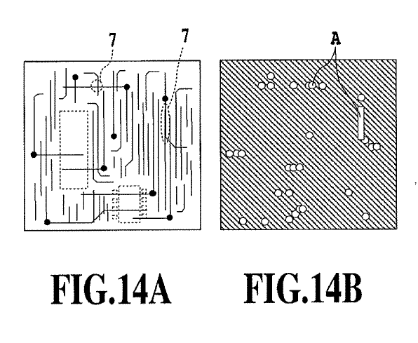

FIG. 14A is a diagram showing the upper and lower conductive patterns in layers. As portions indicated by broken lines enclosing them, regions in which the upper and lower conductive patterns intersect or are close to each other are overlapping portions 7. The term “overlapping portion” here refers to a portion in which when the upper and lower layers are assumed to be stacked directly, the distance between the conductive patterns is less than the electrically isolable distance, that is, they are in close proximity at such a distance that cannot meet the specifications of the circuit board such as electrical characteristics (insulation resistance, withstand voltage etc.). In such a case, the short circuit will occur between the upper and lower conductive patterns if a conductive pattern is present within the predetermined distance in a region of the layer of interest corresponding to the overlapping portions. In other words, the conductive patterns can be formed with carrying out the preliminary ejection of the conductive pattern solution to a region separated from the overlapping portions by the predetermined distance or more with suitably circumventing the regions in the layer of interest corresponding to the overlapping portion. The term “predetermined distance” refers to the “electrically isolable distance” as described above. In addition, since the preliminary ejection of the conductive pattern solution cannot be carried out to regions within the predetermined distance from the connection portions in the layer of interest, these regions must be avoided appropriately.

FIG. 14B shows a region (shaded portion) that enables the preliminary ejection of the conductive pattern solution in the layer of interest, which is determined for the layer of interest of FIG. 13B out of the foregoing consideration. As for the formed preliminary ejection pattern of the conductive pattern solution, it can be either the staggered pattern as shown in FIG. 11A or the solid filled pattern as shown in FIG. 12 because the preliminary ejection of the conductive pattern solution is carried out to the insulating solid filled patterns as in the embodiment 2. The essential thing is that if the thickened solutions remaining in the nozzles are removed by the time of ejection for the essential conductive pattern to be formed next, the forming failure of the connection portions due to the ejection malfunction can be prevented effectively. As for the generating process of the ejection patterns, it is the same as described above except for the preliminary ejection areas.

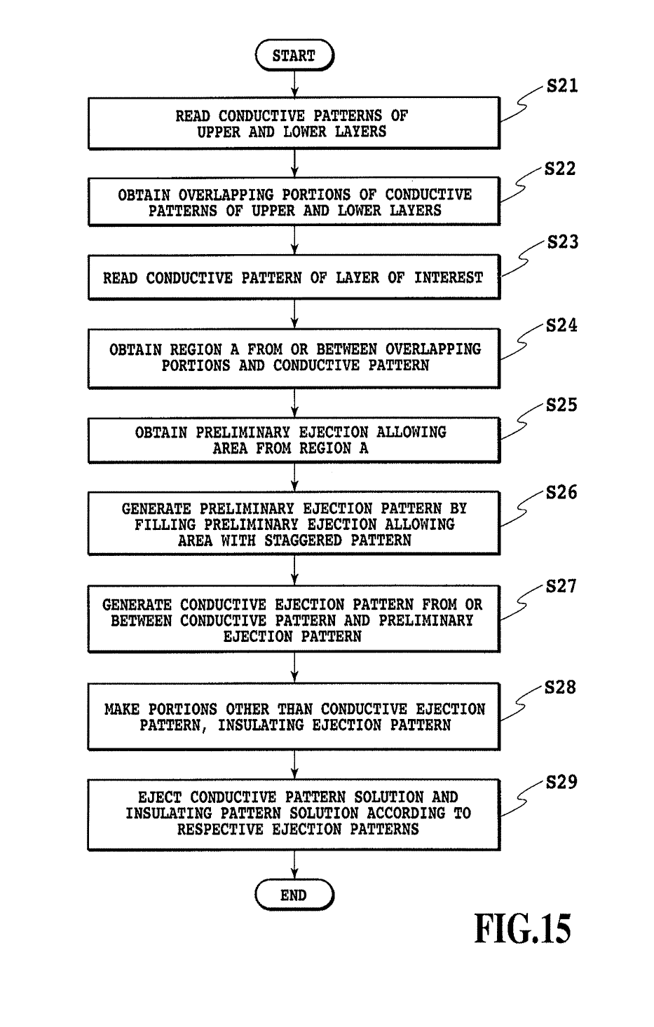

FIG. 15 is a flowchart illustrating the control procedure for implementing the operation of the present embodiment.

First, the conductive pattern data about the circuit patterns stacked on the top and bottom of the layer of interest are read (step S21). After that, the overlapping portions of the upper and lower conductive patterns are obtained (step S22). Subsequently, the conductive patterns of the layer of interest are read (step S23). Then, the regions A are obtained from the OR between the data about the overlapping portions obtained in advance and the data about the conductive patterns of the layer of interest (step S24). After that, each region separated from the regions A by the electrically isolable distance is set as the preliminary ejection allowing area (step S25). Subsequently, the preliminary ejection pattern data is generated for filling the preliminary ejection area with a staggered pattern, for example, according to the same reference as described above (step S26). Subsequently, the ejection pattern data for actually ejecting the conductive pattern solution to the layer of interest is generated from the OR between the conductive patterns of the layer of interest read at step S23 and the preliminary ejection pattern obtained at step S26 (step S27). Furthermore, the real ejection pattern data for actually ejecting the insulating pattern solution to the remaining region is obtained (step S28). The real ejection pattern data of the insulating pattern solution is easily obtained by reversing the real ejection pattern data of the conductive pattern solution. As for these operations, the VRAM 603 area can be used as needed, and the data arranged for each layer or for each conductive pattern or insulating pattern can be utilized.

Then, the heads 610E and 610I are driven according to the real ejection pattern data to eject the conductive pattern solution and insulating pattern solution (step S29), thereby obtaining the desired patterns.

### Embodiment 4

In the present embodiment, attention is directed to the circuit pattern layer for making connections to a power supply and ground. It is assumed here that the circuit board is formed by stacking circuit pattern layers which have the conductive patterns and insulating patterns formed by ejecting both the conductive pattern solution and insulating pattern solution for each layer.

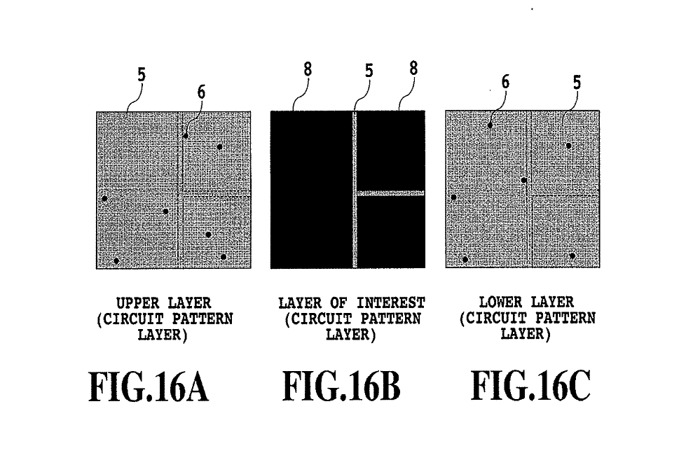

FIGS. 16A-16C are schematic diagrams showing consecutive three circuit pattern layers formed by stacking a plurality of circuit pattern layers on the base material 3. FIG. 16B shows the layer of interest of the present embodiment, which constitutes the circuit pattern layer for making connections to the power supply and ground. The layer of interest is sandwiched by the circuit pattern layers of the upper and lower two layers (FIGS. 16A and 16C). The layer of interest is divided into three power supply planes 8 (conductivity solid filled patterns) by linear insulating patterns 5. Thus, the ejection malfunction of the head 610I can occur during forming the linear insulating patterns in the layer of interest.

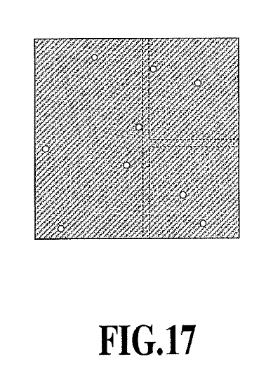

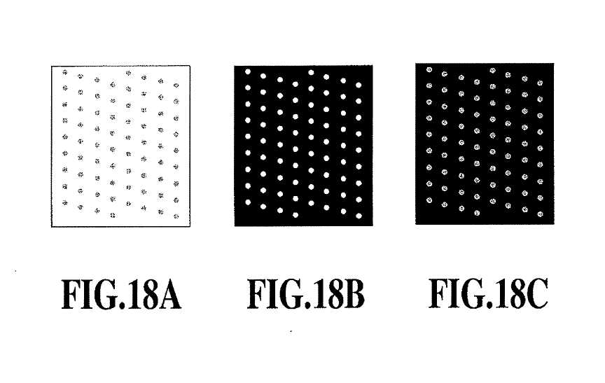

In view of this, paying attention to the relationships between the layer of interest (FIG. 16B) and the upper and lower two layers between which it is sandwiched (FIGS. 16A and 16C), the inventors of the present invention employs anew preliminary ejection process of the insulating pattern solution. Since the layer of interest is a layer for the power supply and ground connection, the circuit patterns of the upper and lower two layers have connection portions 6 for the power supply planes 8. Since the connection portions of the layer of interest make connections with the upper and lower two layers, they cannot be replaced by the insulating patterns. As for the remaining region of the layer of interest, however, its part can be replaced by insulating patterns as long as it satisfies the electrical characteristics as the power supply planes. Accordingly, the region in the layer of interest, which allows the preliminary ejection of the insulating pattern solution, is a shaded portion in FIG. 17. Only, the region must meet the electrical characteristics of the power supply planes. To achieve this, the preliminary ejection pattern of the insulating pattern solution is formed as dispersed patterns in the present embodiment. More specifically, a plurality of nozzles are driven simultaneously at intervals of a predetermined number of nozzles (every four nozzles, for example) in the arrangement direction while shifting the simultaneous driving unit with driving in the scanning direction at intervals of a predetermined number of dots (every four dots, for example), thereby forming the dispersed pattern as shown in FIG. 18A. Such a pattern can prevent the power supply planes from being electrically broken, and can meet the electrical characteristics such as an allowable current and voltage drop of the power supply planes, which are the standards of the circuit board.

FIG. 19 is a flowchart illustrating the control procedure for implementing the operation of the present embodiment.

First, the conductive pattern data about the circuit pattern layers stacked on the top and bottom of the layer of interest are read (step S31). After that, connection portions are detected from the individual conductive patterns, and the regions other than the connection portions are set as the preliminary ejection allowing area (step S32). Subsequently, the preliminary ejection pattern data of the insulating pattern solution is generated to fill the preliminary ejection area with the dispersed patterns that meet the foregoing standard (step S33). Subsequently, the insulating pattern data of the layer of interest is read (step S34). After that, the OR between the insulating pattern data and the preliminary ejection pattern data is obtained to generate the real ejection pattern data for forming the insulating pattern as shown in FIG. 18A (step S35). Subsequently, from the remaining portion, the real ejection pattern data is generated for forming the conductive patterns as shown in FIG. 18B (step S36). The real ejection pattern data of the conductive pattern solution is easily obtained by reversing the real ejection pattern data of the insulating pattern solution. For these operations, the VRAM 603 area can be used as needed.

Then, the heads 610E and 610I are driven according to the real ejection pattern data to eject the conductive pattern solution and insulating pattern solution (step S37), thereby obtaining the desired patterns as shown in FIG. 18C.

As described above, the present embodiment is configured in such a manner as to employ the dispersed patterns as shown in FIG. 18A within the preliminary ejection area shown in FIG. 17, and to carry out the preliminary ejection of the insulating pattern solution. Thus, the present embodiment can make the ejection interval of each nozzle of the ejection head of the insulating pattern solution shorter than the time that will thicken the solutions in the nozzles and might cause the ejection malfunction, thereby being able to prevent the short circuit effectively between the power supply planes due to the malfunction of the insulating pattern.

### Others

The foregoing embodiments employ the circuit board manufacturing apparatus including the carriage 109 that carries the heads 610E and 610I, and the stage 103 that holds and carries the base material. However, it is also possible to employ a circuit board manufacturing apparatus that fixes the heads 610E and 610I and enables the base material to move two dimensionally, or vice versa. Alternatively, instead of the so-called serial scanning apparatuses, it is also possible to employ the line type apparatus that uses a head having nozzles over the area corresponding to the width of the base material, and that has means for moving the base material with respect to the head.

As for the preliminary ejection of the conductivity solution to the mounting region A1 or B1 for mounting an IC chip or the like as shown in FIG. 3B, it can be carried out without any problem if the mounting region and a mounting surface of the chip that makes contact with the mounting region are insulative. For example, as for a capacitor, which is insulated except for its electrodes, it is possible to carry out the preliminary ejection of a conductive solution to the mounting region at which the capacitor is to be placed. In the case of carrying out the preliminary ejection of the insulating solution to such a mounting region, care should be taken not to close or cover the electrodes of the chip and the mounting region. In addition, when the mounting surface of the chip does not make contact with the mounting region, the preliminary ejection to the mounting region can be achieved without any problem regardless of whether the conductivity solution or the insulation solution.

While the present invention has been described with reference to the exemplary embodiments, it is to be understood that the invention is not limited to the disclosed exemplary embodiments. The scope of the following claims is to be accorded the broadest interpretation so as to encompass all such modifications and equivarent structures and functions.

This application claims the benefit of Japanese Patent Application No. 2006-116094, filed Apr. 19, 2006, which is hereby incorporated by reference herein in its entirety.

What is claimed is:

1. A manufacturing process of a circuit board, which employs a head movable with reference to a base material, and forms a pattern for configuring a circuit in a region on the base material by ejecting a solution to the region, the manufacturing process of the circuit board comprising the steps of:
carrying out a primary ejection operation of the head for forming the pattern on the base material; and
carrying out a secondary ejection operation of the head for maintaining ejection performance of the head in a good condition, the secondary ejection operation being independent of the pattern formation,
wherein when an ejection interruption time occurs that can cause an ejection malfunction during the primary ejection operation, the secondary ejection operation is carried out toward an area without the pattern formed by the primary ejection operation in the region.

2. A manufacturing process as claimed in claim 1, wherein the circuit board has a stacking structure having a plurality of the patterns stacked.

3. A manufacturing process as claimed in claim 1, wherein the solution includes at least one of a conductivity solution for forming a conductive pattern and an insulation solution for forming an insulating pattern;
the pattern includes at least one of the conductive pattern and the insulating pattern; and
the head includes at least one of a first head and a second head, the first head forming the conductive pattern by ejecting the conductivity solution, and the second head forming the insulating pattern by ejecting the insulation solution.

4. A manufacturing process as claimed in claim 3, wherein the head that carries out the secondary ejection operation is the first head;
and the area in which the secondary ejection operation is carried out is an area that is separated from the conductive pattern by at least electrically isolable distance.

5. A manufacturing process as claimed in claim 4, wherein the circuit board has a stacking structure having a plurality of the patterns stacked, and the area is electrically isolated by insulating patterns at regions corresponding to the area in upper and lower layers.

6. A manufacturing process as claimed in claim 3, wherein the head that carries out the secondary ejection operation is the second head;
the circuit board has a stacking structure having a plurality of the patterns stacked; and
an area, in which the secondary ejection operation is carried out, is a portion other than a portion connected to conductive patterns corresponding to the area in upper and lower layers, and the secondary ejection operation is carried out not to hamper electrical characteristics of the conductive pattern formed by the first head.

7. A circuit board on which a pattern for configuring a circuit is formed by employing a head movable with reference to a base material, and by ejecting a solution to a region on the base material to form the circuit, the circuit board comprising:
the pattern formed by carrying out a primary ejection operation of the head on the base material; and
a pattern that does not configure the circuit, formed by carrying out a secondary ejection operation of the head for maintaining ejection performance of the head in a good condition, the secondary ejection operation being independent of the pattern formation for the circuit,
wherein the pattern that does not configure the circuit is formed on an area without the pattern formed by the primary ejection operation to configure the circuit, when an ejection interruption time occurs that can cause an ejection malfunction during the primary ejection operation.

8. A circuit board as claimed in claim 7, wherein the area is an area surrounded by the patterns for configuring the circuit.

9. A circuit board as claimed in claim 7, a chip is mounted on the pattern that does not configure the circuit.

10. An apparatus for manufacturing a circuit board, which employs a head movable with reference to a base material, and forms a pattern for configuring a circuit in a region on the base material by ejecting a solution to the region, the apparatus comprising:
means for making the head carry out a primary ejection operation for forming the pattern on the base material and a secondary ejection operation for maintaining ejection performance of the head in a good condition, the secondary ejection operation being independent of the pattern formation; and
means for making the head carry out the secondary ejection toward an area without the pattern formed by the primary ejection operation in the region, when an ejection interruption time occurs that can cause an ejection malfunction during the primary ejection operation.
